(19) United States
(12) Patent Application Publication
(10) Pub. No.: US 2026/0231795 A1
(43) Pub. Date: Aug. 6, 2026

(54) SEMICONDUCTOR DEVICE AND FABRICATION METHOD THEREOF

(71) Applicant: Yangtze Memory Technologies Co., Ltd., Wuhan (CN)

(72) Inventors: Yuhuan ZHENG, Wuhan (CN); Siqian LI, Wuhan (CN); Yonggang YANG, Wuhan (CN); Gang LIU, Wuhan (CN); Jing GAO, Wuhan (CN); Wei XU, Wuhan (CN); Dongmen SONG, Wuhan (CN)

(21) Appl. No.: 19/176,803

(22) Filed: Apr. 11, 2025

Related U.S. Application Data
(63) Continuation of application No. PCT/CN2025/075758, filed on Feb. 5, 2025.

(51) Int. Cl. H10W 70/65; H10B 12/00; H10B 80/00; H10W 70/05; H10W 70/60; H10W 90/00

(52) U.S. Cl. CPC H10W 70/65; H10B 12/053; H10B 12/31; H10B 80/00; H10W 70/093; H10W 70/611; H10W 90/00; H10W 90/792

(57) ABSTRACT

Methods, devices, systems, and techniques for managing conductive structure in semiconductor devices are provided. In one aspect, a semiconductor device includes a first memory cell including a first transistor having a first storage structure and a first semiconductor body and a second memory cell having a second storage structure and a second transistor having a second semiconductor body. The semiconductor device also includes a conductive structure that is between and in contact with the first semiconductor body and the second semiconductor body; a first contact structure including a first end and a second end, where the first end of the first contact structure is in contact with the conductive structure, and the second end of the first contact structure is between the first end and the first storage structure; and a second contact structure that is in contact with the first contact structure.

### CROSS-REFERENCE TO RELATED APPLICATIONS

This application is a continuation of International Application No. PCT/CN2025/075758, filed on February 05, 2025, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures, e.g., vertical transistors.

### SUMMARY

The present disclosure describes methods, devices, systems and techniques for managing vertical structures in three-dimensional (3D) semiconductor devices.

One aspect of the present disclosure features a semiconductor device. The semiconductor device includes a first memory cell including a first transistor and a first storage structure stacked along a first direction, where the first transistor includes a first semiconductor body extending along the first direction; a second memory cell including a second transistor and a second storage structure stacked along the first direction, where the second transistor includes a second semiconductor body extending along the first direction. The semiconductor device also includes a conductive structure that is between and in contact with the first semiconductor body and the second semiconductor body along a second direction perpendicular to the first direction; a first contact structure including a first end and a second end arranged along the first direction, where the first end of the first contact structure is in contact with the conductive structure, and the second end of the first contact structure is between the first end and the first storage structure along the first direction; and a second contact structure that is in contact with the first contact structure and extends along the first direction.

In some implementations, the conductive structure and the first contact structure extend along a third direction perpendicular to the first direction and the second direction.

In some implementations, a cross section of the first contact structure perpendicular to the third direction has a rectangular shape or a T shape.

In some implementations, the second contact structure has a first end and a second end arranged along the first direction, the first end of the second contact structure is in contact with the first contact structure.

In some implementations, the second contact structure extends through the conductive structure along the first direction, and the conductive structure is between the first storage structure and the second end of the second contact structure along the first direction.

In some implementations, the first end of the second contact structure is between the first end of the first contact structure and the second end of the second contact structure along the first direction.

In some implementations, the first transistor includes a first gate structure, the first semiconductor body is between the first gate structure and the conductive structure along the second direction, the first gate structure extends along the third direction and is in contact with a third contact structure extending along the first direction, and the second contact structure and the third contact structure are at different locations along the third direction.

In some implementations, the semiconductor device further includes a first dielectric layer between the first contact structure and the first semiconductor body along the second direction; and a second dielectric layer between the first contact structure and the second semiconductor body along the second direction.

In some implementations, the semiconductor device further includes a first storage node contact structure between and in contact with the first storage structure and the first semiconductor body along the first direction, where the first storage node contact structure includes at least one of a metal layer, a silicide layer, or a doped polysilicon layer.

In some implementations, the semiconductor device includes a first semiconductor structure, a bonding layer, and a second semiconductor structure stacked along the first direction, where the first semiconductor structure and the second semiconductor structure are bonded through the bonding layer; the first semiconductor structure includes an array of memory cells, where the array of memory cells includes the first memory cell and the second memory cell; and the second semiconductor structure includes a peripheral circuit, where the peripheral circuit is coupled to the array of memory cells through conductive bonding contacts in the bonding layer.

Another aspect of the present disclosure features a semiconductor device. The semiconductor device includes a first memory cell including a first transistor and a first storage structure stacked along a first direction, where the first transistor includes a first semiconductor body extending along the first direction; a second memory cell including a second transistor and a second storage structure stacked along the first direction, where the second transistor includes a second semiconductor body extending along the first direction; a conductive structure that is between and in contact with the first semiconductor body and the second semiconductor body along a second direction perpendicular to the first direction; a first contact structure including a first end and a second end arranged along the first direction, where the first end of the first contact structure is in contact with the conductive structure, and the first end of the first contact structure is between the second end and the first storage structure along the first direction; and a second contact structure that is in contact with the first contact structure and extends along the first direction.

In some implementations, the conductive structure and the first contact structure extend along a third direction perpendicular to the first direction and the second direction, and a cross section of the first contact structure perpendicular to the third direction has a rectangular shape or a T shape.

In some implementations, the second contact structure has a first end and a second end arranged along the first direction, the first end of the second contact structure is in contact with the first contact structure, and the conductive structure is between the first storage structure and the second end of the second contact structure along the first direction.

In some implementations, the second contact structure has a first end and a second end arranged along the first direction, the first end of the second contact structure is in contact with the first contact structure, and the conductive structure is between the first storage structure and the first end of the second contact structure along the first direction.

A further aspect of the present disclosure features a method of forming a semiconductor device. The method includes forming a first memory cell and a second memory cell, where the first memory cell includes a first transistor and a first storage structure, the second memory cell includes a second transistor and a second storage structure, and a first semiconductor body of the first transistor and a second semiconductor body of the second transistor extend along a first direction; forming a conductive structure between and in contact with the first semiconductor body and the second semiconductor body along a second direction perpendicular to the first direction; forming a first contact structure, where the first contact structure includes a first end and a second end arranged along the first direction, the first end of the first contact structure is in contact with the conductive structure, and the second end of the first contact structure is between the first end and the first storage structure along the first direction; and forming a second contact structure that is in contact with the first contact structure and extends along the first direction.

In some implementations, the forming the first memory cell and the second memory cell includes forming the first semiconductor body surrounded by a first dielectric layer, the second semiconductor body surrounded by a second dielectric layer, and a trench between the first semiconductor body and the second semiconductor body along the second direction, where the first semiconductor body includes a first end and a second end arranged along the first direction, and the second end of the first semiconductor body is connected to a semiconductor layer.

In some implementations, the forming the conductive structure includes forming a filling structure in the trench, where the filling structure includes a first end and a second end arranged along the first direction, the second end of the filling structure is in contact with a bottom of the trench, and the first end of the filling structure is between the first end of the first semiconductor body and the second end of the first semiconductor body along the first direction; removing a portion of the first dielectric layer and a portion of the second dielectric layer to form a space adjacent to the first end of the filling structure, where the space is between the filling structure and the first end of the first semiconductor body along the first direction, and the space exposes the first semiconductor body and the second semiconductor body in the trench; and forming the conductive structure in the space, where the conductive structure is in contact with the first end of the filling structure.

In some implementations, the forming the first contact structure includes forming the first contact structure extending into the conductive structure, where the first contact structure is between the first end of the filling structure and the first end of the first semiconductor body.

In some implementations, the forming the second contact structure includes forming a contact hole extending along the first direction, where the contact hole extends through the semiconductor layer and the conductive structure and extends into the first contact structure; and forming the second contact structure by filling a conductive material into the contact hole.

In some implementations, the forming the first memory cell further includes forming a gate structure adjacent to the first semiconductor body along the second direction, where the first transistor further includes the gate structure; forming a storage node contact structure in contact with the first semiconductor body along the first direction, where the storage node contact structure includes at least one of a metal layer, a silicide layer, or a doped polysilicon layer; and forming the first storage structure in contact with the storage node contact structure, where the first memory cell further includes the storage node contact structure between the first semiconductor body and the first storage structure.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIGS. 1A-1D illustrate cross-sectional views of example semiconductor devices.

FIG. 1E illustrates a top of an example semiconductor device.

FIGS. 2A to 2I show cross-sectional views of structures of a semiconductor device of FIG. 1A at various stages of a fabrication process.

FIG. 3 illustrates a flow chart of an example semiconductor structure manufacturing process.

FIG. 4 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a DRAM memory) can be formed to have a vertical channel selector tube and a high aspect ratio, which may pose challenges to the manufacturing process. For example, a vertical channel selector tube generally has a floating body, which leads to an accumulation of the charges in the source-leakage junction in the vertical transistor. In other words, floating effect may affect electrical properties of the vertical transistor such as increase gate induced drain leakage (GIDL) when the transistor is in ON or OFF state. In another example, the high aspect ratio may pose challenges in controlling the GIDL. Currently, the leakage current is controlled either by an air gap shielding or metal pick up shield, which can’t effectively control the GIDL as the increasing of the aspect ratio between each memory cell. Therefore, a vertical channel structure that can solve the aforementioned issues is desirable.

In one or more implementations of the present disclosure, an example semiconductor device is provided. The semiconductor device includes a first memory cell including a first vertical transistor and a first storage structure stacked along a first direction, the first vertical transistor includes a first semiconductor body extending along the first direction and a second memory cell including a second vertical transistor and a second storage structure stacked along the first direction, where the second vertical transistor includes a second semiconductor body extending along the first direction. The semiconductor device also includes a conductive structure that is between and in contact with the first semiconductor body and the second semiconductor body along a second direction perpendicular to the first direction; a first contact structure including a first end and a second end arranged along the first direction, where the first end of the first contact structure is in contact with the conductive structure, and the second end of the first contact structure is between the first end and the first storage structure along the first direction; and a second contact structure that is in contact with the first contact structure and extends along the first direction.

Implementations of the present disclosure can provide one or more of the following technical advantages and/or benefits. First, the conductive structure is in contact with the semiconductor bodies of two adjacent vertical transistors. The conductive structure can reduce the floating effect of the semiconductor bodies of the two adjacent vertical transistors. In other words, the conductive structure can reduce the charge accumulated in the semiconductor bodies during the operation of the device and mitigate the floating effect of the semiconductor bodies. Second, the first contact structure is in contact with the conductive structure and a second contact structure. The first contact structure and the second contact structure are used to remove the accumulated charges in the semiconductor bodies through the conductive structure, which improve the device’s performance during operation by reducing the GIDL. In other words, the first and the second contact structure can reduce power consumption (such as lower static power usage caused by the reduced leakage current and lower dynamic power consumption during memory device operation). Third, the addition of the conductive structure and the first and second contact structures can help lower the error rate of the memory cells. Fourth, the conductive structure, the first contact structure, and the second contact structure can be easily integrated in the existing device, which reduce the fabrication cost. Fifth, the described techniques can lead to uniform device parameters and consistent performance across different devices. In addition, this approach also allows for easier process implementation and improved control during manufacturing, thereby enhancing manufacturing reliability and increasing the overall production yield.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

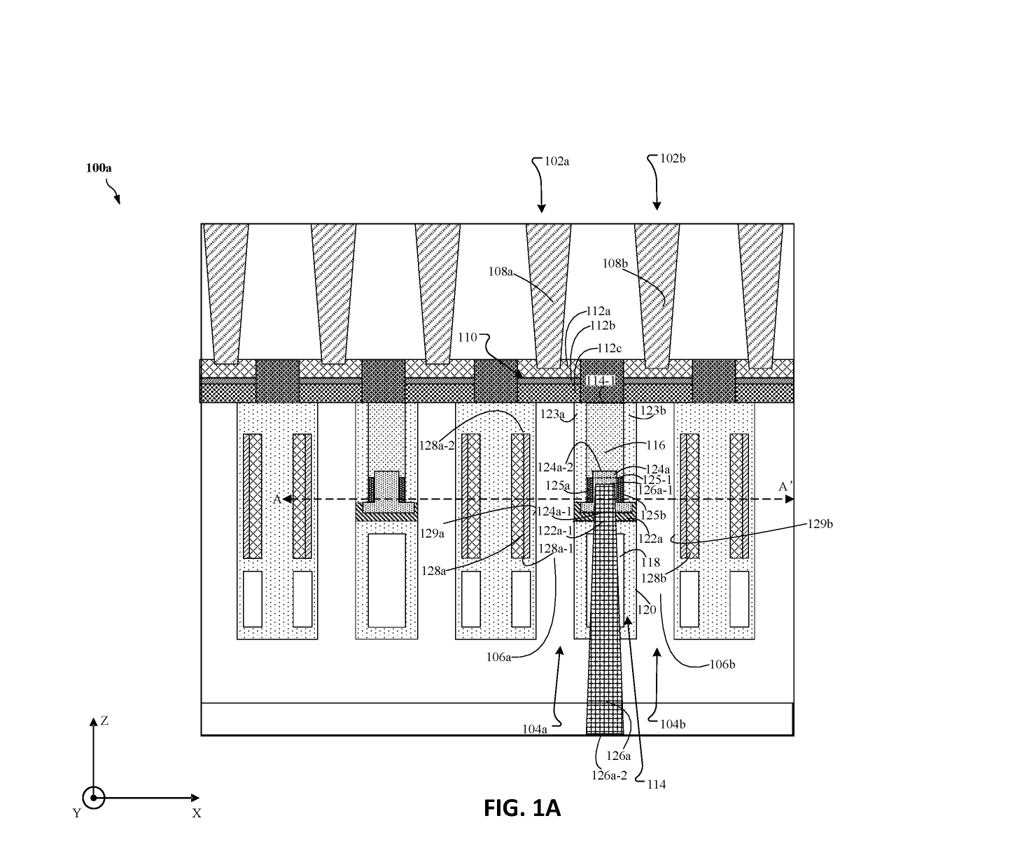

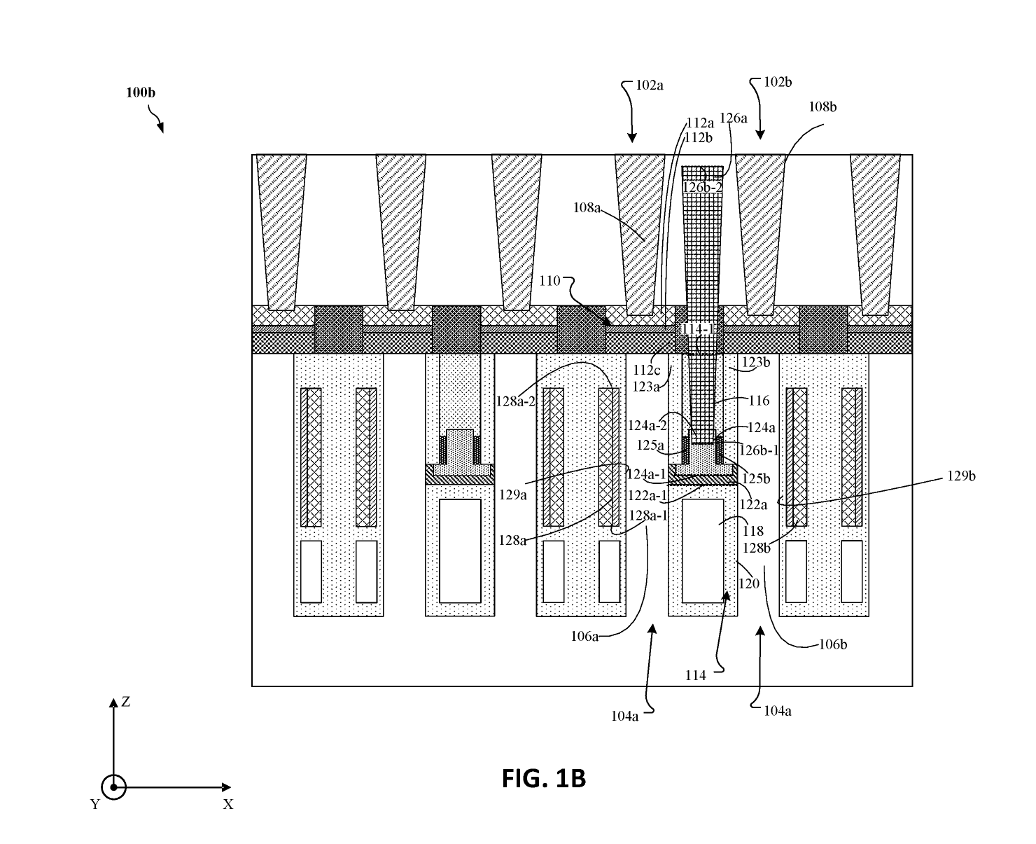

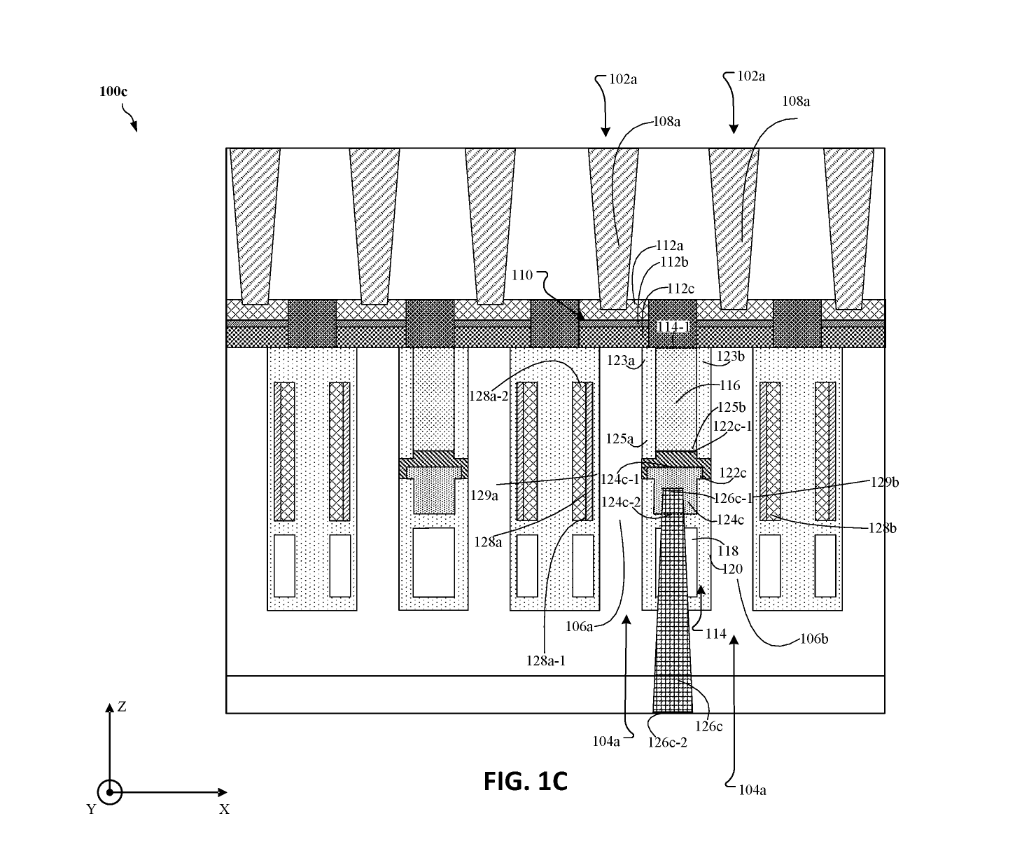

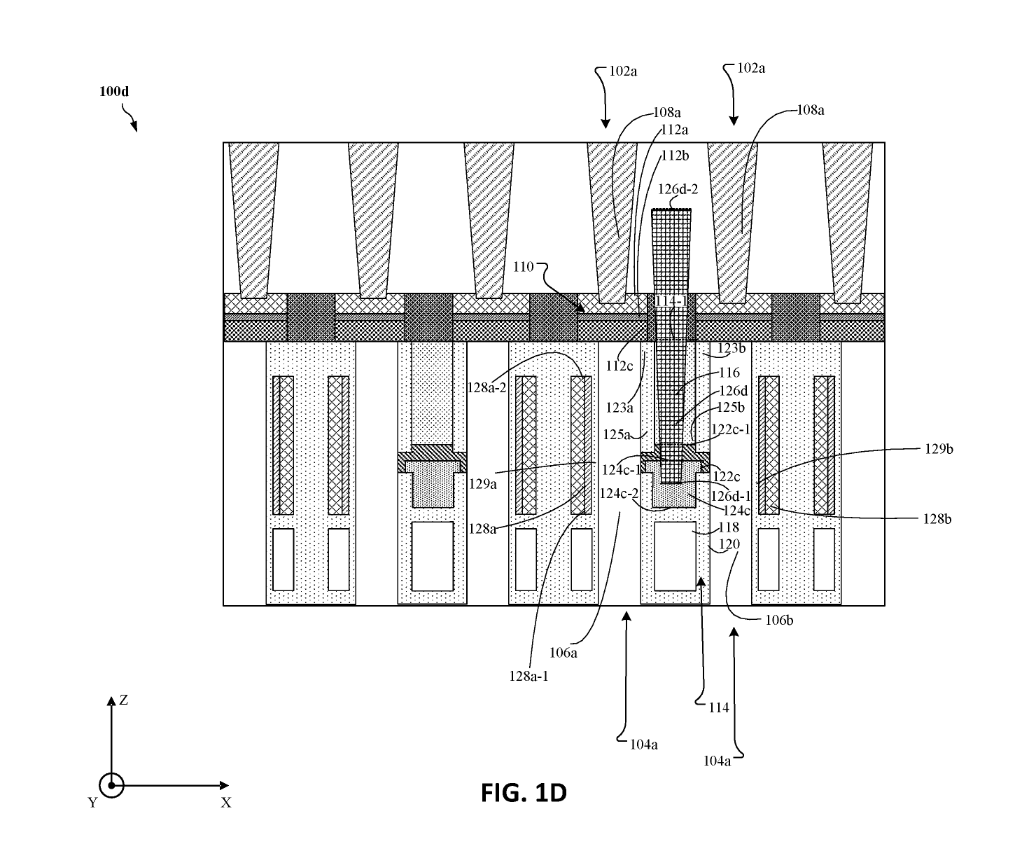

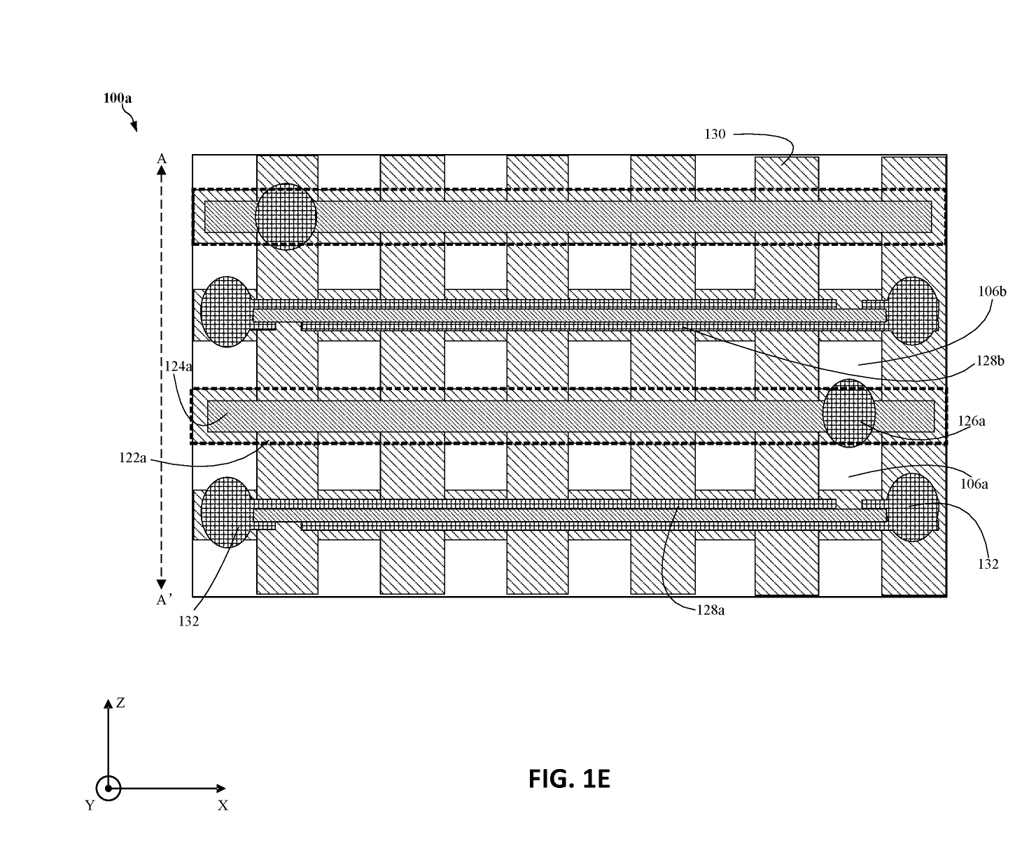

It is noted that X, Y, and Z axes (also referred to as X, Y, and Z directions) are included in FIGS. 1A-1E to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a cross-sectional view of a semiconductor device 100a. The semiconductor device 100a can be a 3D dynamic random-access memory (DRAM). It is understood that FIG. 1A is for illustrative purposes only and may not necessarily reflect the actual device structure (e.g., interconnections) in practice.

As shown in FIG. 1A, the semiconductor device 100a includes a first memory cell 102a. The first memory cell 102a can include a vertical transistor 104a having a first semiconductor body 106a. The first semiconductor body 106a extends in a vertical direction (e.g., the Z direction). The first memory cell 102a also includes a first storage structure 108a stacked on top of the first semiconductor body 106a along the Z direction. The first storage structure 108a is coupled to the first semiconductor body 106a. In some implementations, the first memory cell 102a can be a DRAM cell and the first storage structure 108a can be a capacitor that is coupled to the vertical transistor 104a of the DRAM cell.

The semiconductor device 100a also includes a second memory cell 102b. The second memory cell 102b can include a second vertical transistor 104b having a second semiconductor body 106b. The second semiconductor body 106b extends in a vertical direction (e.g., the Z direction. The second memory cell 102b also includes a second storage structure 108b stacked on top of the second semiconductor body 106b along the Z direction. The second storage structure 108b is coupled to the second semiconductor body 106b. In some implementations, the second memory cell 102b can be a DRAM cell and the second storage structure 108b can be a capacitor that is coupled to the vertical transistor 104b of the DRAM cell. As shown in FIG. 1A, the second memory cell 102b can be adjacent to the first memory cell 102a along a horizontal direction (e.g., the X direction) perpendicular to the Z direction. In some implementations, the first storage structure 108a and the second storage structures 108b can have, but not limited to pillar structure, a cylindrical structure or any other suitable structures thereof.

In some implementations, as shown in FIG. 1A, the semiconductor bodies 106a – 106b and the storage structures 108a – 108b of the semiconductor device 100a are coupled by storage node contact structures 110 respectively. For example, the first semiconductor body 106a and the first storage structure 108a are connected by a first storage node contact structure 110. The first storage node contact structure 110 is connected to the first semiconductor body 106a and the first storage structure 108a along the Z direction. In some implementations, the first storage node contact structures 110 includes at least one of a metal layer 112a, a silicide layer 112b, or a doped polysilicon layer 112c. In some implementations, the metal layer 112a includes a conductive material including, but not limited to W, Co, Cu, Al, TiN, TaN, or any combination thereof. The silicide layer 112b includes metal silicide such as WSi, CoSi, CuSi, AlSi, or any other suitable metal silicides having higher conductivities than doped silicon. The doped polysilicon layer 112c includes a doped semiconductor layer such as Boron or Phosphorus doped polysilicon. In some implementations, ohmic contacts are created at an interface between the first semiconductor body 106a and the doped polysilicon layer 112c and at an interface between the metal layer 112a and the first storage structure 108a. The ohmic contacts can reduce resistance between the first semiconductor body 106a and the first storage structure 108a. In other words, the ohmic contacts can reduce loss during signal transfer between the first storage structure 108a and the first semiconductor body 106a, which can ensure a stable signal transfer between the first storage structure 108a and the first semiconductor body 106a.

In some implementations, the first semiconductor body 106a and the second semiconductor body 106b are separated by an isolation structure 114. The isolation structure 114 extends along the Z direction. In some implementations, the length of the isolation structure along the Z direction is the same as the length of the semiconductor bodies 106a–106b of the vertical transistors 104a–104b along the Z direction. The isolation structure 114 can be used to electrically isolate the first semiconductor body 106a and the second semiconductor body 106b to mitigate charge interference between the two semiconductor bodies 106a–106b. A first portion of the isolation structure 114 can include a dielectric structure 116. The dielectric structure 116 extends along the Z direction from a first end 114-1 of the dielectric structure. A second portion of the isolation structure 114 can include an air gap 118. In some implementations, the air gap 118 is surrounded by an insulation layer 120. In some implementations, the insulation layer 120 includes dielectric materials such as silicon oxide and silicon nitride.

As shown in FIG. 1A, the semiconductor device 100a includes a conductive structure 122a. The conductive structure 122a is between the dielectric structure 116 and the air gap 118 along the Z direction. The conductive structure 122a is between and in contact with the first semiconductor body 106a and the second semiconductor body 106b along the X direction. In some implementations, the conductive structure 122a includes a semiconductor material such as poly Si or doped semiconductor material so that interfaces between the conductive structure 122a and the semiconductor bodies 106a – 106b can have an ohmic contact. The semiconductor material or doped semiconductor material of the conductive structure 122a can increase a bonding strength between the conductive structure 122a and the semiconductor bodies 106a – 106b.

The semiconductor device 100a also includes a first contact structure 124a. The first contact structure includes a first end 124a-1 and a second end 124a-2 arranged along the Z direction. The first end 124a-1 of the first contact structure 124a is in contact with the conductive structure 122a. The second end 124a-2 of the first contact structure 124a is between the first end 124a-1 and the first storage structure 108a along the Z direction. In some implementations, the first contact structure 124a includes metal silicide such as WSi, CoSi, CuSi, AlSi, or any other suitable metal silicides having higher conductivities than doped silicon. In some implementations, the first contact structure 124a can include a conductive material (such as W) stacked on a metal silicide material (e.g., WSi) along the Z direction, where the metal silicide material is in contact with the conductive structure 122a, ensuring low resistivity between the interface of the conductive structure 122a and the first contact structure 124a at the first end 124a-1 of the first contact structure 124a. In some implementations (as shown in FIG. 1E), the conductive structure 122a and the first contact structure extend along a second horizontal direction (e.g., the Y direction) perpendicular to the X direction and the Z direction. In some implementations, as shown in FIG. 1A, a cross-section of the first contact structure 124a perpendicular to the Y direction has a T shape, with a base extending along the X direction and a body extending along the Z direction. The base of the first contact structure 124a is in contact with the conductive structure 122a. The body of the first contact structure 124a is stacked on the base of the first contact structure 124a and is between the conductive structure 122a and the first storage structure 108a along the Z direction. Alternatively, in some implementations (not shown in FIG. 1A), a cross-section of the first contact structure perpendicular to the Y direction has a rectangular shape. In some implementations, the cross-section of the first contact structure 124a can include, but not limited to the T shape, the rectangular shape or any other suitable shapes, where the first end 124a-1 of the first contact structure 124a is in contact with the conductive structure 122a.

In some implementations, the first contact structure 124a includes a metal silicide material. The metal silicide material of the first contact structure 124a can be formed through a reaction between the semiconductor material of the conductive structure 122a and a conductive material, resulting in an increase in the volume of the conductive material used for the reaction. For example, the conductive material can be tungsten (W) and the semiconductor material of the conductive structure 122a can be polysilicon (Poly Si), and the first contact structure 124a can be tungsten silicide (WSi), which is formed by a reaction between the W and the Poly Si. In some implementations, the first contact structure 124a can extend beyond the first and second high-k layers 125a and 125b along the Z direction. For example, as shown in FIG. 1A, a distance between the second end 124a-2 of the first contact structure 124a and the first storage structure 108a is smaller than a distance between the end 125-1 of the first and the second high-k layer 125a and 125b and the first storage structure along the Z direction. Alternatively, in some implementations, the first contact structure 124a may not extend beyond the first and second high-k layers 125a and 125b along the Z direction. For example (not shown in FIG. 1A), a distance between the first end 124a-1 and the second end 124a-2 of the first contact structure is no greater than a distance between the end 125-1 of the first and the second high-k layer 125a and 125b and the end 122a-1 of the first conductive structure 122a along the Z direction.

The semiconductor device 100a includes a first dielectric layer 123a that is between the first contact structure 124a and the first semiconductor body 106a along the X direction and a second dielectric layer 123b that is between the first contact structure 124a and the second semiconductor body 106b along the X direction. In some implementations, the first dielectric layer 123a and the second dielectric layer 123b include a dielectric material (e.g., SiO₂). In some implementations, the first contact structure 124a extends into the dielectric structure 116, where the dielectric structure 116 is between the first dielectric layer 123a and the second dielectric layer 123b along the X direction. In some implementations, as shown in FIG. 1A, the semiconductor further includes a first high-k layer 125a and a second high-k layer 125b. The first high-k layer 125a is between the first dielectric layer 123a and the first contact structure 124a along the X direction. The second high-k layer 125b is between the second dielectric layer 123b and the first contact structure 124a. In some implementations, the first high-k layer 125a and the second high-k layer 125b can include a high-k dielectric material including, but not limited to, Al2O3, HfO2, Ta2O5, ZrO2, TiO2, or any combination thereof.

As shown in FIG. 1A, the semiconductor device 100a includes a second contact structure 126a that is in contact with the first contact structure 124a. The second contact structure 126a extends along the Z direction. The second contact structure 126a has a first end 126a-1 and a second end 126a-2 arranged along the Z direction. The first end 126a-1 of the second contact structure 126a is in contact with the first contact structure 124a. In some implementations, as shown in FIG. 1A, the second contact structure 126a extends through the conductive structure 122a along the Z direction. The conductive structure 122a is between the first storage structure 108a and the second end 126a-2 of the second contact structure 126a along the Z direction. In some implementations (not shown in FIG. 1A), the second contact structure 126a extends into the conductive structure 122a without extending through the conductive structure 122a, where the second contact structure 126a is coupled to the first contact structure 124a via the conductive structure 122a. In some implementations, the first end 126a-1 of the second contact structure 126a is between the first end 124a-1 of the first contact structure 124a and the second end 126a-2 of the second contact structure 126a along the Z direction. In some implementations, the second contact structure 126a can include a conductive material including, but not limited to, W, Co, Cu, Al, TiN, TaN, or any combination thereof. In some implementations, the conductive structure 122a, the first contact structure 124a, and the second contact structure 126a are connected to a metal layer with a lower potential to create a path for accumulated charges in the semiconductor bodies 106a–106b of the vertical transistors 104a–104b. The accumulated charges can be drawn away from the semiconductor bodies 106a–106b to the metal layer, which can reduce the floating effect of the memory cell.

As shown in FIG. 1A, the first vertical transistor 104a includes a first gate structure 128a in contact with the first semiconductor body 106a. In some implementations, as shown in FIG. 1A, the first gate structure is in contact with the first semiconductor body 106a through a dielectric layer 129a. The first semiconductor body 106a is between the first gate structure 128a and the conductive structure 122a along the second direction. In some implementations, the first gate structure 128a extends along the Y direction. In some implementations, the second vertical transistor 104b includes a second gate structure 128b in contact with the second semiconductor body 106b. In some implementations, the second gate structure is in contact with the first semiconductor body 106b through a dielectric layer 129b. The second semiconductor body is between the second gate structure 128b and the conductive structure 122a along the second direction. In some implementations, the second gate structure 128b extends along the Y direction. In some implementations, the conductive structure 122a, the first contact structure 124a, the second contact structure 126a, the first semiconductor body 106a, and the second semiconductor body 106b are between the first gate structure 128a and the second gate structure 128b along the X direction. The first gate structure 128a has a first end 128a-1 and a second end 128a-2 that are opposite to each other along the Z direction. In some implementations, the length between an end 122a-1 of the conductive structure 122a and the second end 124a-2 of the first contact structure 124a is smaller than the length of the first gate structure 128a along the Z direction. The end 122a-1 of the conductive structure 122a is between the first end 124a-1 of the first contact structure 124a and the second end 126a-2 of the second contact structure 126a along the Z direction. In some implementations, the end 122a-1 of the conductive structure 122a and the second end 124a-2 of the first contact structure 124a are between the first end 128a-1 and the second end 128a-2 of the gate structure 128 along the Z direction.

In some implementations, the semiconductor device 100a includes a first semiconductor structure, a bonding layer, and a second semiconductor structure stacked along the Z direction. The first semiconductor structure and the second semiconductor structure are bonded through the bonding layer. The first semiconductor structure includes an array of memory cells, where the array of memory cells includes the first memory cell 102a and the second memory cell 102b. In some implementations, the array of memory cells can include multiple groups of the conductive structures 122a, the first contact structures 124a and the second contact structures 126a, where each of the conductive structures 122a and each of the first contact structures 124a are between a corresponding first memory cell 102an and the second memory cell 102b. The second semiconductor structure includes a peripheral circuit, where the peripheral circuit is coupled to the array of memory cells through conductive bonding contacts in the bonding layer. In some implementations, the bonding layer can include a dielectric material that electrically isolates the conductive bonding contacts. In some implementations, the peripheral circuits include a plurality of vertical transistors (e.g., planar vertical transistors and/or 3D vertical transistors). In some examples, the peripheral circuits are formed using complementary metal-oxide-semiconductor (CMOS) technology, and the first semiconductor structure can be also formed on a semiconductor die that can be referred to as a control die or a CMOS die.

In some implementations, the first semiconductor structure further includes an interconnect layer above the peripheral circuits to transfer electrical signals to and from the peripheral circuits. The interconnect layer can include a plurality of interconnects (also referred to herein as “contacts”), including lateral interconnect lines and VIA contacts. The interconnect layer can further include one or more interlay dielectric (ILD) layers in which the interconnect lines and via contacts can form. That is, the interconnect layer can include interconnect lines and via contacts in multiple ILD layers. In some implementations, peripheral circuits are coupled to one another through the interconnects in the interconnect layer. The interconnects in interconnect layer can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

FIG. 1B illustrates a cross-section view of an example semiconductor device 100b. In some implementations, the semiconductor device 100b can be similar to the semiconductor device 100a of FIG. 1A, except a second contact structure 126b of the semiconductor device 100b has a different arrangement compared to the second contact structure 126a of the semiconductor device 100a of FIG. 1A.

As shown in FIG. 1B, the semiconductor device 100b includes a second contact structure 126b that is in contact with the first contact structure 124a. The second contact structure 126b extends along the Z direction. The second contact structure 126b has a first end 126b-1 and a second end 126b-2 arranged along the Z direction. The first end 126b-1 of the second contact structure 126b is in contact with the first contact structure 124a. In some implementations, as shown in FIG. 1B, the second contact structure 126b extends into the first contact structure 124a without extending into the conductive structure 122a along the Z direction. The second end 126b-2 of the second contact structure 126b is on the same side of the first storage structure 108a with respect to the conductive structure 122a along the Z direction. The first end 126b-1 of the second contact structure 126b is between the first end 124a-1 and the second end 124a-2 of the first contact structure 124a along the Z direction. In some implementations (not shown in FIG. 1A), the second contact structure 126b extends through the first contact structure 124a and into the conductive structure 122a along the Z direction. In some implementations, the second contact structure 126b can include a conductive material including, but not limited to, W, Co, Cu, Al, TiN, TaN, or any combination thereof. In some implementations, the conductive structure 122a, the first contact structure 124a, and the second contact structure 126b are connected to a metal layer with a lower potential to create a path for accumulated charges in the semiconductor bodies 106a–106b of the vertical transistors 104a–104b. The accumulated charges can be drawn away from the semiconductor bodies 106a–106b to the metal layer, which can reduce the floating effect of the memory cell.

FIG. 1C illustrates a cross-section view of an example semiconductor device 100c. In some implementations, the semiconductor device 100c can be similar to the semiconductor device 100a of FIG. 1A, except a conductive structure 122c, a first contact structure 124c, and a second contact structure 126c of the semiconductor device 100c has a different arrangement compared to the conductive structure 122a, the first contact structure 124a, and the second contact structure 126a of the semiconductor device 100a of FIG. 1A.

As shown in FIG. 1C, the semiconductor device 100c includes a conductive structure 122c. In some implementations, the conductive structure 122c is between the dielectric structure 116 and the air gap 118 along the Z direction. As shown in FIG. 1C, the conductive structure 122c is between and in contact with the first semiconductor body 106a and the second semiconductor body 106b along the X direction. In some implementations, the conductive structure 122c includes a semiconductor material such as poly-Si or doped semiconductor material so that interfaces between the conductive structure 122c and the semiconductor bodies 106a–106b can have an ohmic contact. The semiconductor material or doped semiconductor material of the conductive structure 122c can increase the bonding strength between the conductive structure 122c and the semiconductor bodies 106a–106b.

The semiconductor device 100c also includes a first contact structure 124c. The first contact structure includes a first end 124c-1 and a second end 124c-2 arranged along the Z direction. The first end 124c-1 of the first contact structure 124c is in contact with the conductive structure 122c. The first end 124c-1 of the first contact structure 124c is between the second end 124a-2 and the first storage structure 108a along the Z direction. In some implementations, the first contact structure 124c includes metal silicide such as WSi, CoSi, CuSi, AlSi, or any other suitable metal silicides having higher conductivities than doped silicon. In some implementations, the first contact structure 124c can include a metal silicide material (e.g., WSi) stacked on a conductive material (such as W) along the Z direction, where the metal silicide material is in contact with the conductive structure 122c, ensuring low resistivity between the interface of the conductive structure 122c and the first contact structure 124c at the first end 124c-1 of the first contact structure 124c. In some implementations (as shown in FIG. 1E), the conductive structure 122c and the first contact structure extend along a second horizontal direction (e.g., the Y direction) perpendicular to the X direction and the Z direction. In some implementations (not shown in FIG. 1A), a cross-section of the first contact structure perpendicular to the Y direction has a rectangular shape. In some implementations, as shown in FIG. 1A, a cross-section of the first contact structure 124c perpendicular to the Y direction has a T shape, with a base extending along the X direction and a body extending along the Z direction. The base of the first contact structure 124c is in contact with the conductive structure 122c. The base of the first contact structure 124c is stacked on the body of the first contact structure. The base of the first contact structure 124c is between the body and the first storage structure 108a along the Z direction.

The semiconductor device 100c includes a first dielectric layer 123a a between the first contact structure 124c and the first semiconductor body 106a and a second dielectric layer 123b between the first contact structure 124c and the second semiconductor body 106b. In some implementations, the first dielectric layer 123a and the second dielectric layer 123b can each include a dielectric material (e.g., SiO₂). In some implementations, the first contact structure 124c extends into the dielectric structure 116, where the dielectric structure 116 is between the first dielectric layer 123a and the second dielectric layer 123b along the X direction. In some implementations, as shown in FIG. 1A, the semiconductor further includes a first high-k layer 125a and a second high-k layer 125b. The first high-k layer 125a is between the first dielectric layer 123a and the first contact structure 124c along the X direction. The second high-k layer 125b is between the second dielectric layer 123b and the first contact structure 124c. In some implementations, the first high-k layer 125a and the second high-k layer 125b can each include a high-k dielectric material including, but not limited to, Al2O3, HfO2, Ta2O5, ZrO2, TiO2, or any combination thereof.

As shown in FIG. 1C, the semiconductor device 100c includes a second contact structure 126c that is in contact with the first contact structure 124c. The second contact structure 126c extends along the Z direction. The second contact structure 126c has a first end 126c-1 and a second end 126c-2 arranged along the Z direction. The first end 126c-1 of the second contact structure 126c is in contact with the first contact structure 124c. The conductive structure 122c is between the first storage structure 108a and the second end 126c-2 of the second contact structure 126c along the first direction. In some implementations, the second contact structure 126c can include a conductive material including, but not limited to W, Co, Cu, Al, TiN, TaN, or any combination thereof. In some implementations, the conductive structure 122c, the first contact structure 124c, and the second contact structure 126c are connected to a metal layer with a lower potential to create a path for accumulated charges in the semiconductor bodies 106a – 106b of the vertical transistors 104a – 104b. The accumulated charges can be drawn away from the semiconductor bodies 106a – 106b to the metal layer, which can reduce the floating effect of the memory cell.

In some implementations, a length between an end 122c-1 of the conductive structure 122c and the second end 124c-2 of the first contact structure 124c is smaller than a length of the first gate structure 128a along the Z direction. The end 122c-1 of the conductive structure 122c is between the first end 124c-1 of the first contact structure 124a and the first storage structure 108a along the Z direction. In some implementations, the end 122c-1 of the conductive structure 122c and the second end 124c-2 of the first contact structure 124c are between the first end 128a-1 and the second end 128a-2 of the gate structure 128 along the Z direction.

FIG. 1D illustrates a cross-section view of an example semiconductor device 100d. In some implementations, the semiconductor device 100d can be similar to the semiconductor device 100c of FIG. 1C, except a second contact structure 126d of the semiconductor device 100d has a different arrangement compared to the second contact structure 126c of the semiconductor device 100c of FIG. 1C.

As shown in FIG. 1D, the semiconductor device 100d includes a second contact structure 126d that is in contact with the first contact structure 124c. In some implementations, as shown in FIG. 1D, the second contact structure 126d extends through the conductive structure 122c and into the first contact structure 124c along the Z direction. The second contact structure 126d has a first end 126d-1 and a second end 126d-2 arranged along the Z direction. The first end 126d-1 of the second contact structure 126d is in contact with the first contact structure 124c. The conductive structure 122c is between the first storage structure 108a and the first end 126d-1 of the second contact structure 126d along the first direction. In some implementations (not shown in FIG. 1D), the second contact structure 126d extends into the conductive structure 122c without extending into the first contact structure 124c, where the first contact structure 124c is coupled with the second contact structure 126d via the conductive structure 122c. In some implementations, the second contact structure 126d can include a conductive material including, but not limited to, W, Co, Cu, Al, TiN, TaN, or any combination thereof. In some implementations, the conductive structure 122c, the first contact structure 124c, and the second contact structure 126d are connected to a metal layer with a lower potential to create a path for accumulated charges in the semiconductor bodies 106a–106b of the vertical transistors 104a–104b. The accumulated charges can be drawn away from the semiconductor bodies 106a–106b to the metal layer, which can reduce the floating effect of the memory cell.

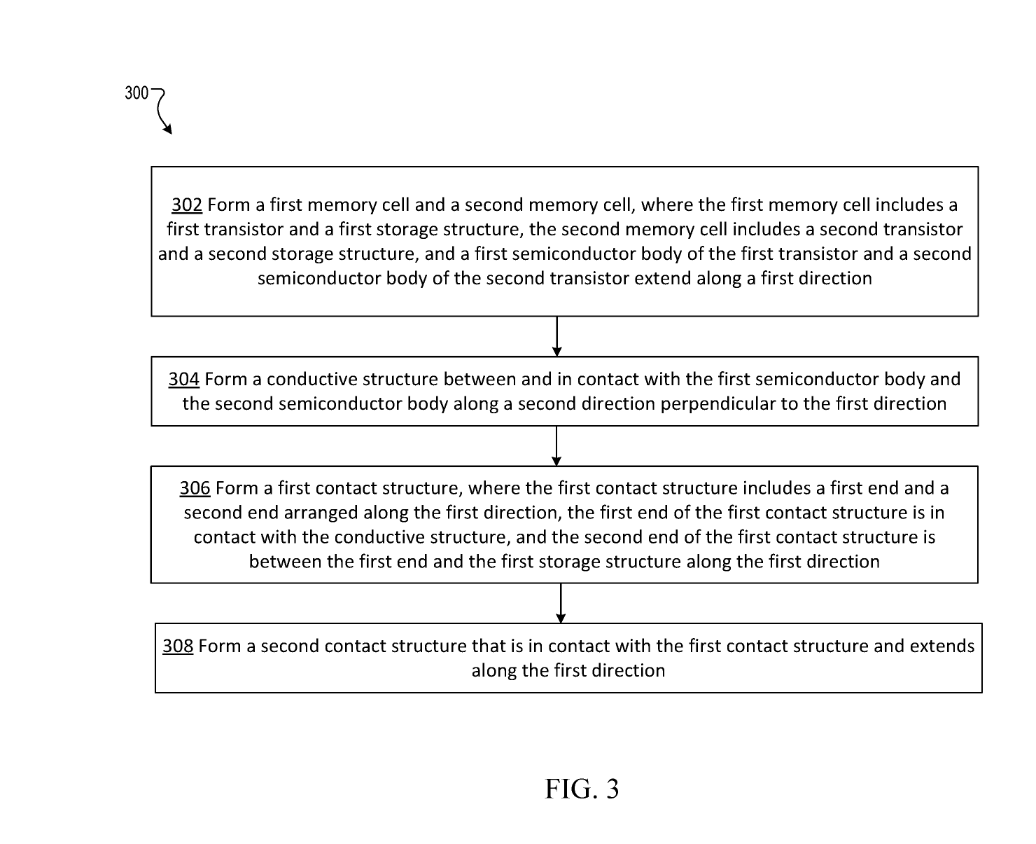

FIG. 1E illustrates a top view of the example semiconductor device 100a of FIG. 3A along cut line AA’ of FIG. 3A. As shown in FIG. 1E, the semiconductor device 100a can include an array of memory cells arranged in rows extending in the Y direction and columns extending in the X direction. The array of memory cells includes the first memory cell 102a and the second memory cell 102b. Each of the columns of the array of memory cells is separated by isolation structures 130. The conductive structure 122a and the first contact structure 124a extend along the Y direction between two adjacent rows of the semiconductor bodies of the memory cells. The second contact structure 126a is in contact with the first contact structure 124a at a side of the first contact structure 124a. In some implementations, the first gate structure 128a and the second gate structure 128b extend along the Y direction. The first gate structure 128a and the second gate structure 128b extend through the isolation structures 130. In some implementations, the first gate structure 128a and the second gate structure 128b are in contact with corresponding third contact structures 132 (also referred to as word line contacts) along the Z direction. In some implementations, as shown in FIG. 1E, the second contact structure 126a is separated from the third contact structure 132 along the X direction, and the second contact structure 126a and the third contact structures 132 are at different locations along the Y direction.

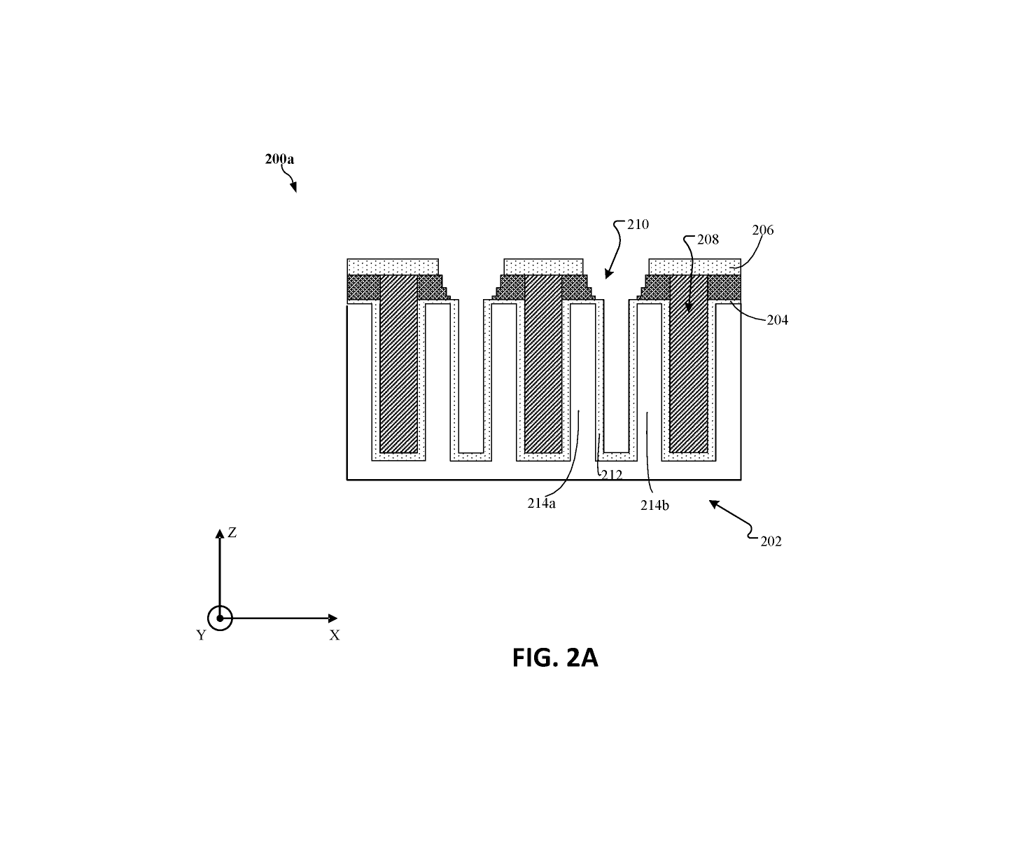

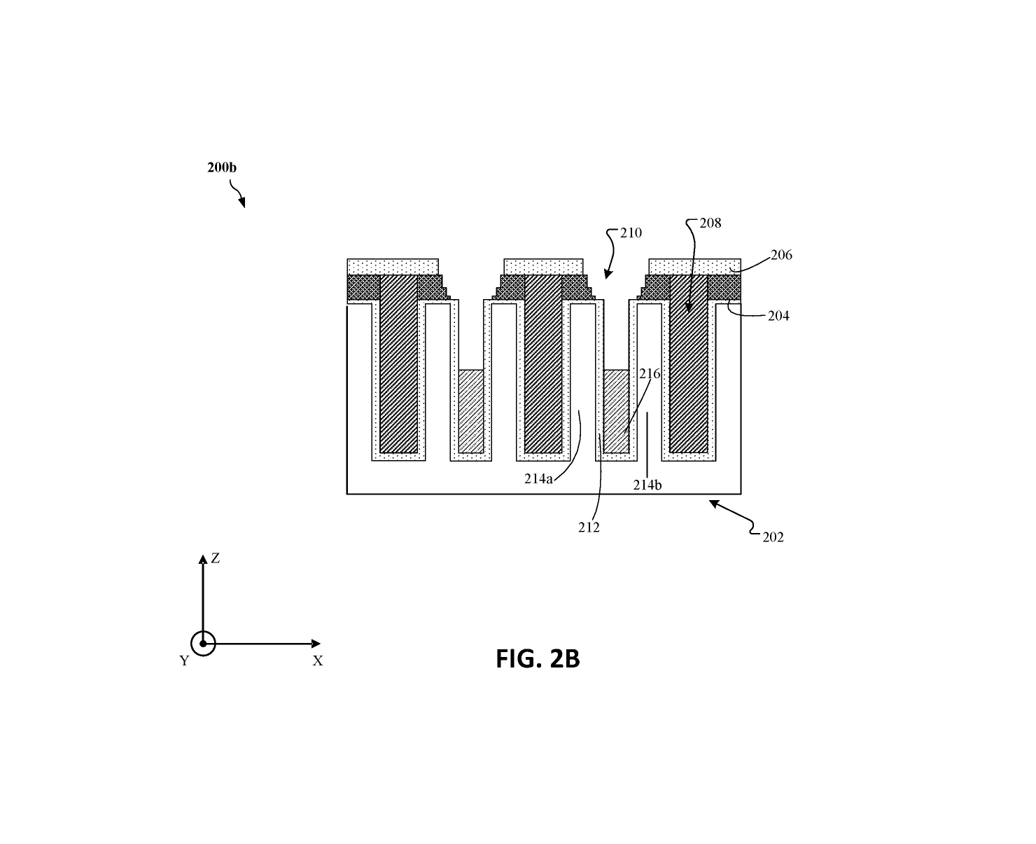

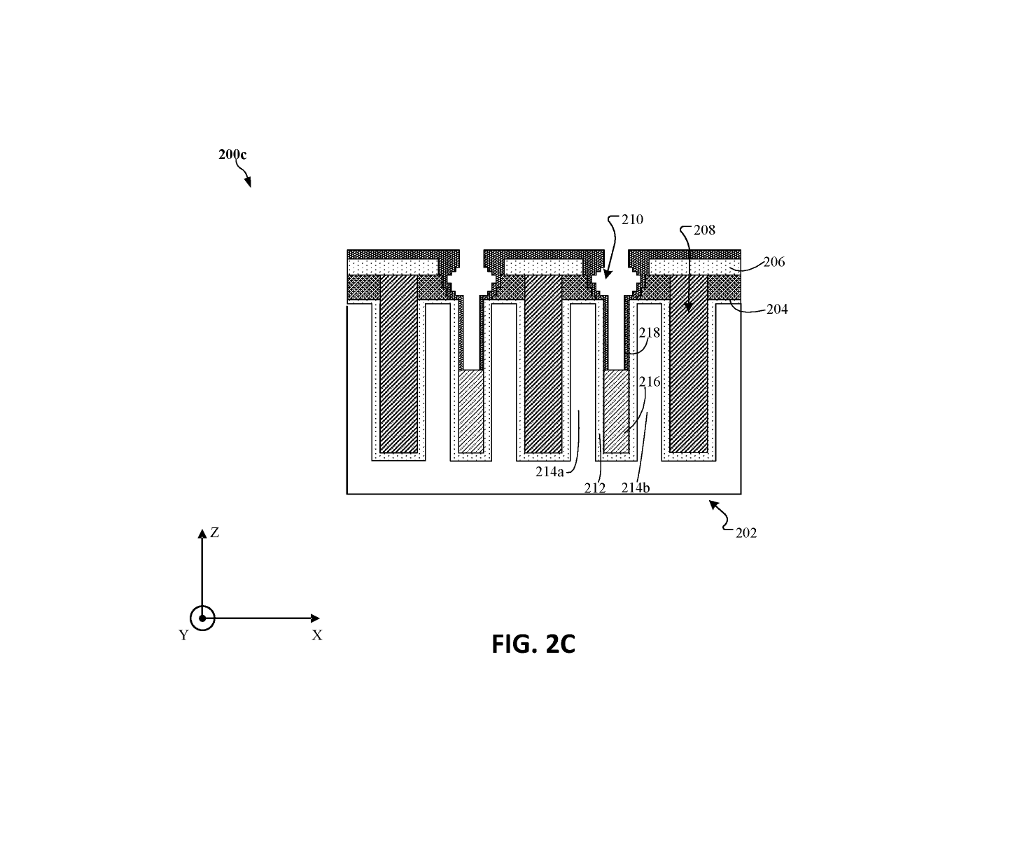

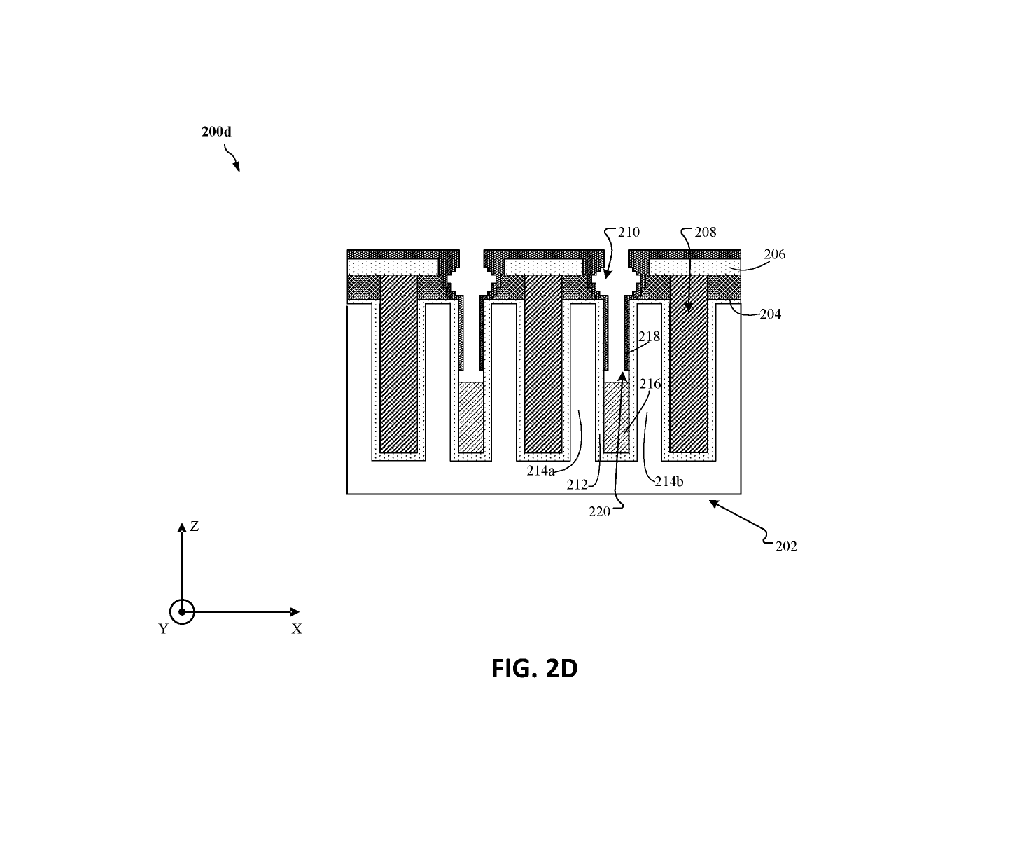

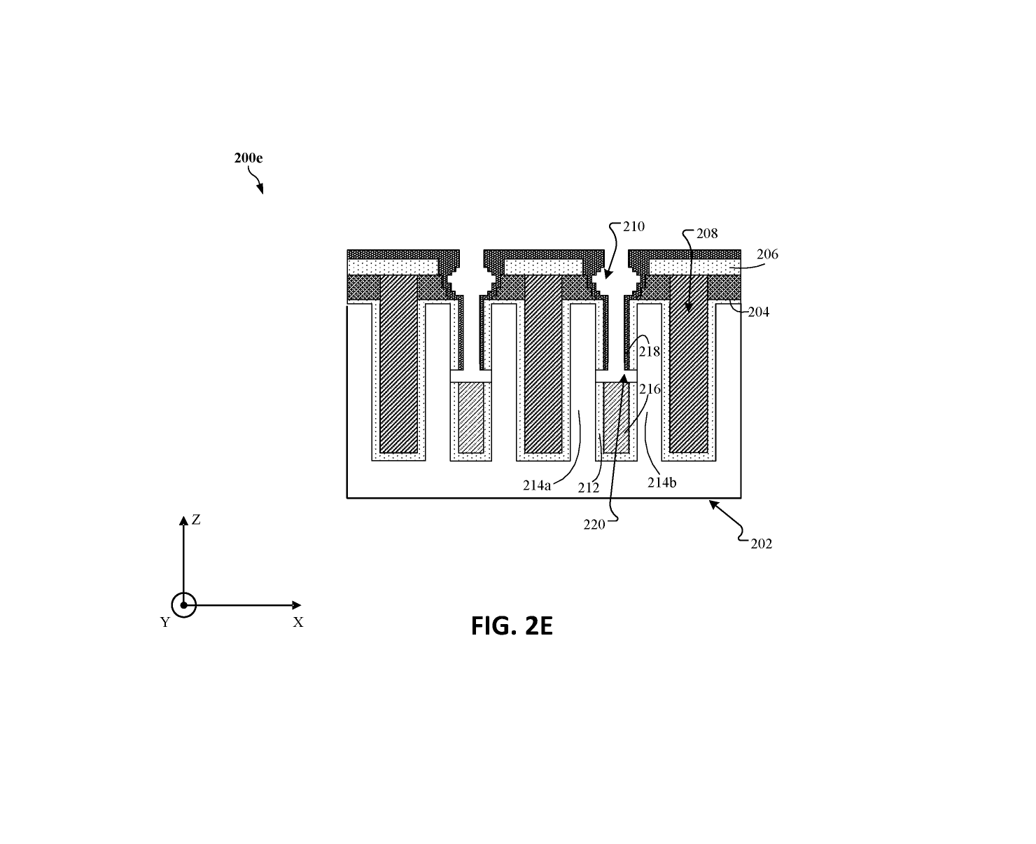

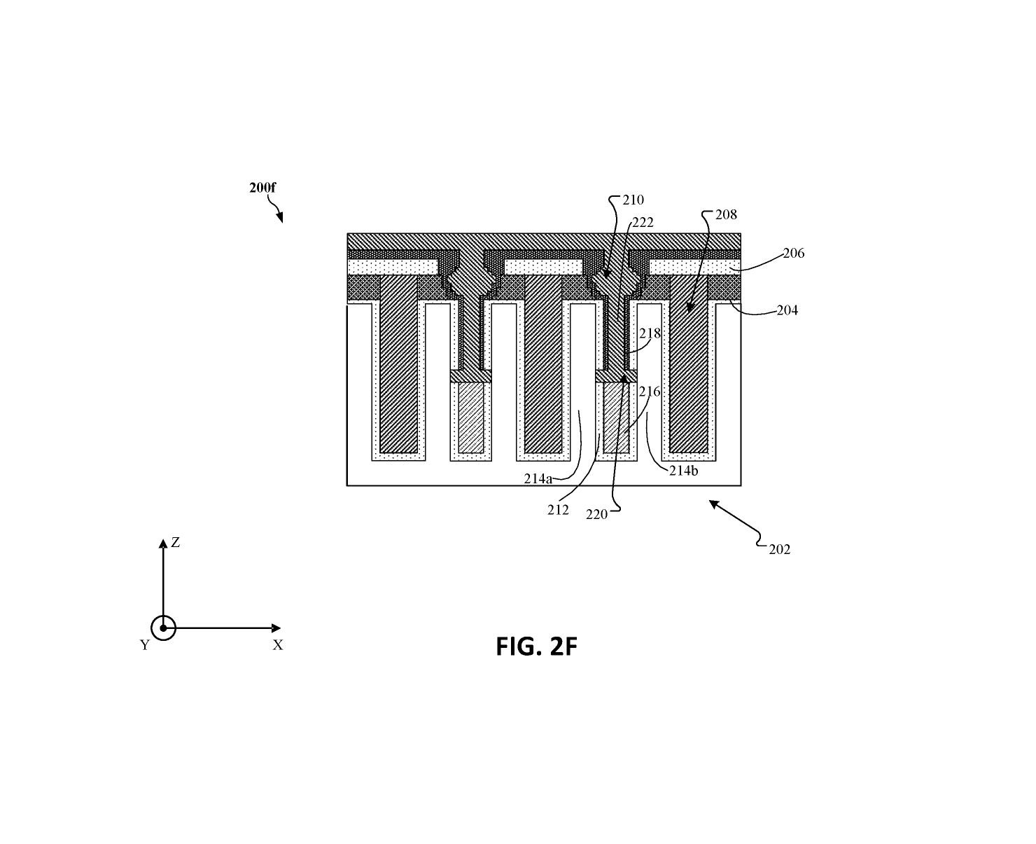

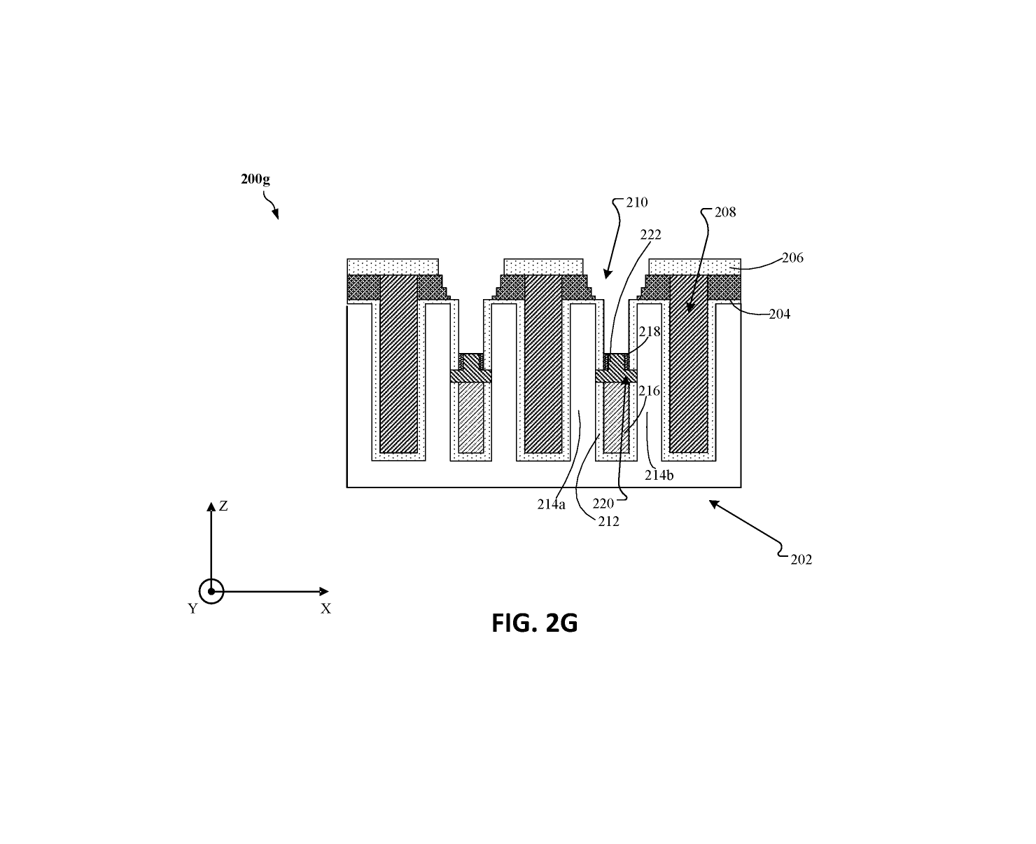

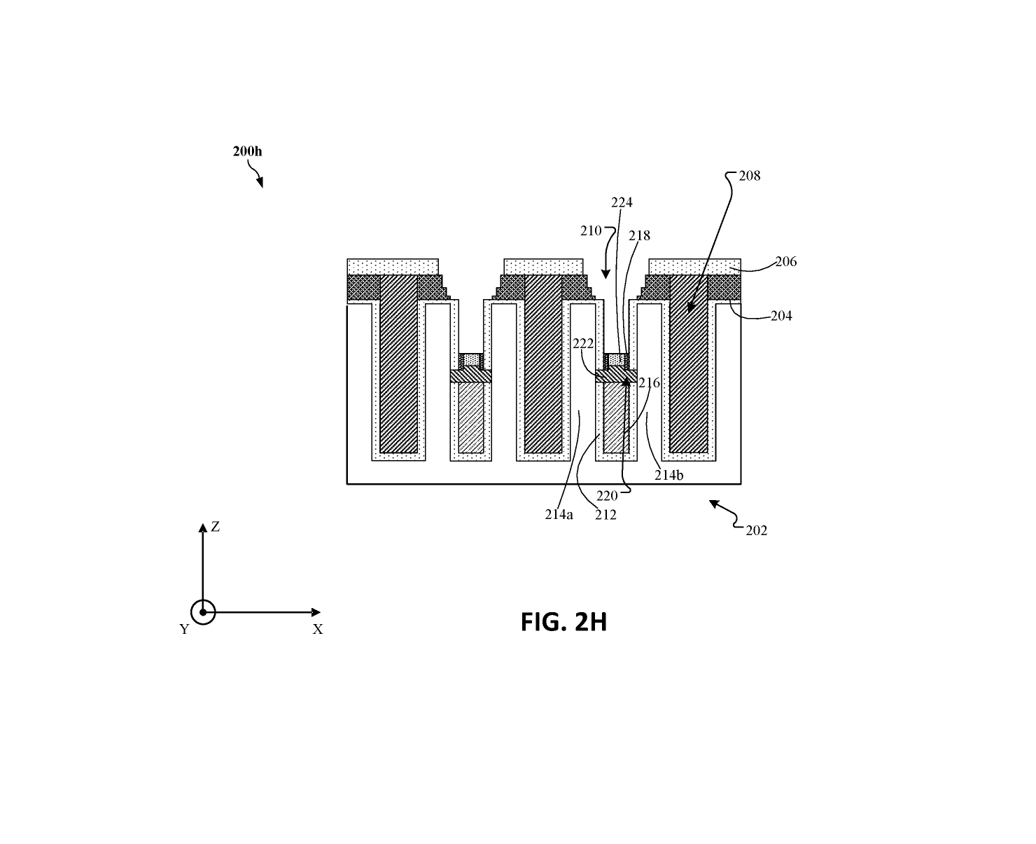

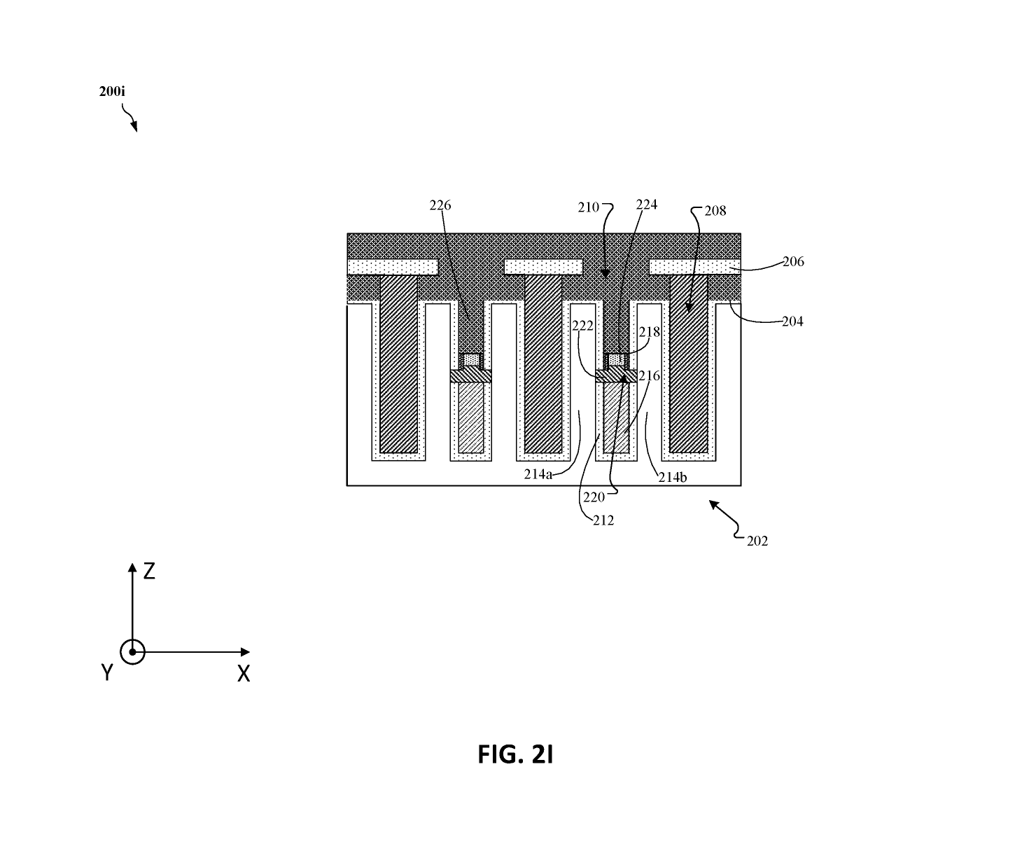

FIGS. 2A-2I illustrate an example process of fabricating a semiconductor device, such as the semiconductor device 100a as illustrated in FIGS. 1A. FIGS. 2A-2I show cross sectional views of example semiconductor structures at various stages of the fabrication process.

FIG. 2A illustrate a semiconductor structure 200a. The semiconductor structure 200a can include a substrate 202, a first dielectric layer 204 stack on top of the substrate 202 along a vertical direction (e.g., the Z direction), and a second dielectric layer 206 stacked on top of the first dielectric layer 204 along the Z direction. The semiconductor structure 200a can include one or more first trenches 208 filled with a first sacrificial material surrounded by a dielectric material. The semiconductor structure 200a also includes one or more second trenches 210. An inner wall of the one or more second trenches are coated by a third dielectric layer 212. The one or more first trenches 208 and the one or more second trenches 210 are alternating with each other along a horizontal direction (e.g., the X direction) perpendicular to the Z direction. Each of the one or more second trenches 210 is between a first semiconductor body 214a and a second semiconductor body 214b along the X direction.

FIG. 2B illustrates a semiconductor structure 200b, which can be formed by filling a portion of the second trench 210 with a second sacrificial material to form a sacrificial structure 216.

FIG. 2C illustrates a semiconductor structure 200c, which can be formed by depositing a high-k dielectric material on a side wall of a remaining portion of the second trench 210 and the second dielectric layer 206 to form a high-k layer 218. In some implementations, as shown in FIG. 2C, the high-k layer 218 is in contact with the sacrificial structure 216 along the Z direction.

FIG. 2D illustrates a semiconductor structure 200d, which can be formed by removing a portion of the sacrificial structure 216 in contact with the high-k layer 218 along the Z direction to form a space 220. As shown in FIG. 2D, the space 220 is between the high-k layer 218 and the sacrificial structure 216 along the Z direction.

FIG. 2E illustrates a semiconductor structure 200e, which can be formed by removing a portion of the third dielectric layer 212 on the sidewall of the second trench 210. The portion of the third dielectric layer 212 is in contact with the space 220 along the X direction. After the removing of the portion of the third dielectric layer 212, the space 220 is in contact with the first semiconductor body 214a and the second semiconductor body 214b along the X direction.

FIG. 2F illustrates a semiconductor structure 200f, which can be formed by filling the space 220 and the second trench 210 with a semiconductor material to form a filling structure 222. A portion of the filling structure 222 is in contact with the first semiconductor body 214a and the second semiconductor body 214b along the X direction.

FIG. 2G illustrates a semiconductor structure 200g, which can be formed by removing a portion of the filling structure 222 and a portion of the high-k layer 218. As shown in FIG. 2G, a cross-section of a remaining portion of the filling structure 222 perpendicular to a second horizontal direction (e.g., the Y direction) has a T shape having a base extending along the X direction and a body extending along the Z direction. The base of the filling structure 222 is in contact with the first semiconductor body 214a and the second semiconductor body 214b along the X direction. In some implementations (not shown in FIG. 2G), the high-k layer 218 can be fully removed to simplify fabrication process and improve process control.

As shown in FIG. 2H, a semiconductor structure 200h is formed. The semiconductor structure 200h can include a first contact structure 224. The first contact structure 224 can be formed by diffusing a conductive material (e.g., W) into the filling structure 222 to form metal silicide (e.g., WSi) in the body of the filling structure 222. In some implementations, the first contact structure 224 can include a conductive layer stacked on top of a silicide layer along the Z direction. The first contact structure 224 can be formed by diffusing the conductive material into the filling structure 222 to form the silicide layer and depositing a conductive material on the silicide layer to form the conductive layer. In some implementations, the metal silicide of the first contact structure 224 can be diffused into the base of the filling structure 222, where a cross-section of the first contact structure 224 perpendicular to the Y direction has a T shape.

FIG. 2I illustrates a semiconductor structure 200i, which can be formed by depositing a dielectric material into the second trench 210 and on top of the second dielectric layer 206 to form a dielectric structure 226. Other fabrication processes can also be performed on the semiconductor structure 200i to form the semiconductor device 100a. For example, the sacrificial structure 216 can be removed to form an air gap (e.g., the air gap 118 of FIG. 1A). Gate structures (e.g., the first gate structure 128a and the second gate structure 128b of FIG. 1A) can be formed in the one or more first trenches 208. A second contact structure can be formed in the second trench 210. The second contact structure (e.g., the second contact structure 126a of FIG. 1A) is in contact with the first contact structure 224 along the Z direction.

FIG. 3 illustrates a flow chart of an example process 300. The process 300 can be performed to form a semiconductor device (e.g., the semiconductor device 100a illustrated by FIG. 1A or the semiconductor device 100c illustrated by FIG. 1C). The process 300 can be described in view of FIGS. 2A-2I. The process 300 can include one or more steps of the fabrication process of forming the semiconductor structures in FIGS. 2A-2I. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a first memory cell (e.g., the first memory cell 102a of FIG. 1A) and a second memory cell (e.g., the second memory cell 102b of FIG. 1A) are formed, where the first memory cell includes a first vertical transistor (e.g., the first vertical transistor 104a of FIG. 1A) and a first storage structure (e.g., the first storage structure 108a of FIG. 1A), the second memory cell includes a second vertical transistor (e.g., the second vertical transistor 104b of FIG. 1A) and a second storage structure (e.g., the second storage structure 108b of FIG. 1A), and a first semiconductor body (e.g., the first semiconductor body 106a of FIG. 1A) of the first vertical transistor and a second semiconductor body (e.g., the second semiconductor body 106b of FIG. 1A) of the second vertical transistor extend along a first direction (e.g., the Z direction).

At operation 304, a conductive structure (e.g., the conductive structure 122a of FIG. 1A) is formed. The conductive structure between and in contact with the first semiconductor body and the second semiconductor body along a second direction (e.g., the X direction) perpendicular to the first direction

At operation 306, a first contact structure (e.g., the first contact structure 124a of FIG. 1A or the first contact structure 224 of FIG. 2H) is formed, where the first contact structure includes a first end (e.g., the first end 124a-1 of FIG. 1A) and a second end (e.g., the second end 124a-2 of FIG. 1A) arranged along the first direction, the first end of the first contact structure is in contact with the conductive structure, and the second end of the first contact structure is between the first end and the first storage structure along the first direction.

At operation 308, a second contact structure (e.g., the second contact structure 126a of FIG. 1A) is formed. The second contact structure is in contact with the first contact structure and extends along the first direction.

In some implementations, the forming the first memory cell and the second memory cell includes forming the first semiconductor body surrounded by a first dielectric layer (e.g., the first dielectric layer 123a of FIG. 1A), the second semiconductor body surrounded by a second dielectric layer (e.g., the second dielectric layer 123b of FIG. 1A), and a trench (e.g., the second trench 210 of FIG. 2A) between the first semiconductor body and the second semiconductor body along the second direction , where the first semiconductor body includes a first end and a second end arranged along the first direction, and the second end of the first semiconductor body is connected to a semiconductor layer.

In some implementations, the forming the conductive structure includes forming a filling structure (e.g., the sacrificial structure 216 of FIG. 2B) in the trench, where the filling structure includes a first end and a second end arranged along the first direction, the second end of the filling structure is in contact with a bottom of the trench, and the first end of the filling structure is between the first end of the first semiconductor body and the second end of the first semiconductor body along the first direction; removing a portion of the first dielectric layer and a portion of the second dielectric layer to form a space (e.g., the space 220 of FIG. 2D) adjacent to the first end of the filling structure, where the space is between the filling structure and the first end of the first semiconductor body along the first direction, and the space exposes the first semiconductor body and the second semiconductor body in the trench; and forming the conductive structure in the space , where the conductive structure is in contact with the first end of the filling structure.

In some implementations, the forming the first contact structure includes forming the first contact structure extending into the conductive structure, where the first contact structure is between the first end of the filling structure and the first end of the first semiconductor body.

In some implementations, the forming the second contact structure includes forming a contact hole extending along the first direction, where the contact hole extends through the semiconductor layer and the conductive structure and extends into the first contact structure; and forming the second contact structure by filling a conductive material into the contact hole.

In some implementations, the forming the first memory cell further includes forming a gate structure (e.g., the first gate structure 128a of FIG. 1A) adjacent to the first semiconductor body along the second direction, where the first vertical transistor further includes the gate structure; forming a storage node contact structure (e.g., the storage node contact structure 110 of FIG. 1A) in contact with the first semiconductor body along the first direction, where the storage node contact structure includes at least one of a metal layer (e.g., the metal layer 112a of FIG. 1A), a silicide layer (e.g., the silicide layer 112b of FIG. 1A), or a doped polysilicon layer (e.g., the doped polysilicon layer 112c of FIG. 1A); and forming the first storage structure in contact with the storage node contact structure, where the first memory cell further includes the storage node contact structure between the first semiconductor body and the first storage structure.

In some implementations, the gate structure is formed before the forming of the conductive structure, the first contact structure, and the second contact structure.

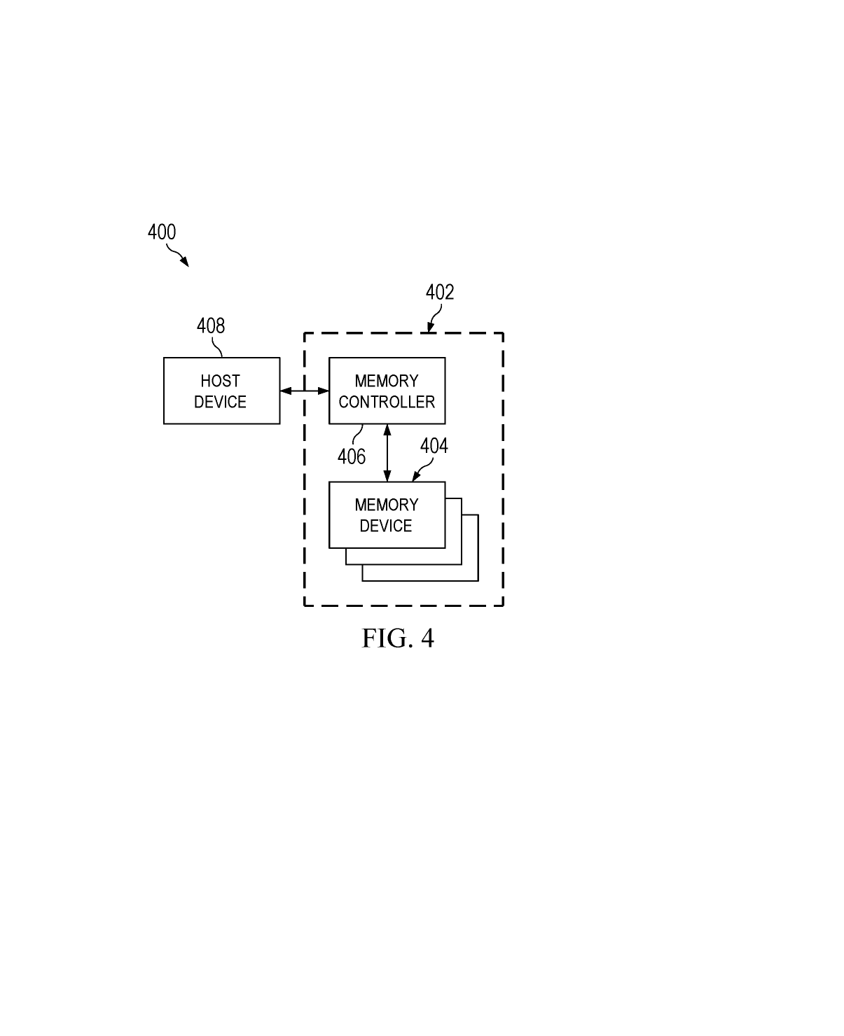

FIG. 4 illustrates a block diagram of a system 400 having one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 4, the system 400 can include a host device 408 and a memory system 402 having one or more 3D memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more 3D memory devices 404.

A 3D memory device 404 can be any 3D memory device disclosed herein, such as a 3D memory device depicted in FIGS. 1A-1D. In some implementations, a 3D memory device 404 includes a DRAM memory. Memory controller 406 (a.k.a., a controller circuit) is coupled to 3D memory device 404 and host device 408. Consistent with implementations of the present disclosure, 3D memory device 404 can include a plurality of conductive interconnections through a cover layer that ar1e in contact with conductive pads in a conductive pad layer, and memory controller 406 can be coupled to 3D memory device 404 through at least one of the plurality of conductive interconnections. Memory controller 406 is configured to control 3D memory device 404. For example, memory controller 406 may be configured to operate a plurality of channel structures via word lines. Memory controller 406 can manage data stored in 3D memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of 3D memory device 404, such as read, erase, and program (or write) operations. Memory controller 406 can also be configured to manage various functions with respect to the data stored or to be stored in 3D memory device 404 including, but not limited to bad-block management, garbage collection, logical-to-physical address conversion, wear leveling, etc. In some implementations, memory controller 406 is further configured to process error correction codes (ECCs) with respect to the data read from or written to 3D memory device 404. Any other suitable functions may be performed by memory controller 406 as well, for example, formatting 3D memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more 3D memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single 3D memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature’s relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+-.10%, .+-.20%, or .+-.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first memory cell comprising a first transistor and a first storage structure stacked along a first direction, wherein the first transistor comprises a first semiconductor body extending along the first direction;
a second memory cell comprising a second transistor and a second storage structure stacked along the first direction, wherein the second transistor comprises a second semiconductor body extending along the first direction;
a conductive structure that is between and in contact with the first semiconductor body and the second semiconductor body along a second direction perpendicular to the first direction;
a first contact structure comprising a first end and a second end arranged along the first direction, wherein the first end of the first contact structure is in contact with the conductive structure, and the second end of the first contact structure is between the first end and the first storage structure along the first direction; and
a second contact structure that is in contact with the first contact structure and extends along the first direction.

2. The semiconductor device of claim 1, wherein the conductive structure and the first contact structure extend along a third direction perpendicular to the first direction and the second direction.

3. The semiconductor device of claim 2, wherein a cross section of the first contact structure perpendicular to the third direction has a rectangular shape or a T shape.

4. The semiconductor device of claim 1, wherein the second contact structure has a first end and a second end arranged along the first direction, the first end of the second contact structure is in contact with the first contact structure.

5. The semiconductor device of claim 4, wherein the second contact structure extends through the conductive structure along the first direction, and the conductive structure is between the first storage structure and the second end of the second contact structure along the first direction.

6. The semiconductor device of claim 4, wherein the first end of the second contact structure is between the first end of the first contact structure and the second end of the second contact structure along the first direction.

7. The semiconductor device of claim 2, wherein the first transistor comprises a first gate structure, the first semiconductor body is between the first gate structure and the conductive structure along the second direction, the first gate structure extends along the third direction and is in contact with a third contact structure extending along the first direction, and the second contact structure and the third contact structure are at different locations along the third direction.

8. The semiconductor device of claim 1, further comprising:
a first dielectric layer between the first contact structure and the first semiconductor body along the second direction; and
a second dielectric layer between the first contact structure and the second semiconductor body along the second direction.

9. The semiconductor device of claim 1, further comprising:
a first storage node contact structure between and in contact with the first storage structure and the first semiconductor body along the first direction, wherein the first storage node contact structure comprises at least one of a metal layer, a silicide layer, or a doped polysilicon layer.

10. The semiconductor device of claim 1, wherein:
the semiconductor device comprises a first semiconductor structure, a bonding layer, and a second semiconductor structure stacked along the first direction, wherein the first semiconductor structure and the second semiconductor structure are bonded through the bonding layer;
the first semiconductor structure comprises an array of memory cells, wherein the array of memory cells comprises the first memory cell and the second memory cell; and
the second semiconductor structure comprises a peripheral circuit, wherein the peripheral circuit is coupled to the array of memory cells through conductive bonding contacts in the bonding layer.

11. A semiconductor device, comprising:
a first memory cell comprising a first transistor and a first storage structure stacked along a first direction, wherein the first transistor comprises a first semiconductor body extending along the first direction;
a second memory cell comprising a second transistor and a second storage structure stacked along the first direction, wherein the second transistor comprises a second semiconductor body extending along the first direction;
a conductive structure that is between and in contact with the first semiconductor body and the second semiconductor body along a second direction perpendicular to the first direction;
a first contact structure comprising a first end and a second end arranged along the first direction, wherein the first end of the first contact structure is in contact with the conductive structure, and the first end of the first contact structure is between the second end and the first storage structure along the first direction; and
a second contact structure that is in contact with the first contact structure and extends along the first direction.

12. The semiconductor device of claim 11, wherein the conductive structure and the first contact structure extend along a third direction perpendicular to the first direction and the second direction, and a cross section of the first contact structure perpendicular to the third direction has a rectangular shape or a T shape.

13. The semiconductor device of claim 11, wherein the second contact structure has a first end and a second end arranged along the first direction, the first end of the second contact structure is in contact with the first contact structure, and the conductive structure is between the first storage structure and the second end of the second contact structure along the first direction.

14. The semiconductor device of claim 11, wherein the second contact structure has a first end and a second end arranged along the first direction, the first end of the second contact structure is in contact with the first contact structure, and the conductive structure is between the first storage structure and the first end of the second contact structure along the first direction.

15. A method, comprising:
forming a first memory cell and a second memory cell, wherein the first memory cell comprises a first transistor and a first storage structure, the second memory cell comprises a second transistor and a second storage structure, and a first semiconductor body of the first transistor and a second semiconductor body of the second transistor extend along a first direction;
forming a conductive structure between and in contact with the first semiconductor body and the second semiconductor body along a second direction perpendicular to the first direction;
forming a first contact structure, wherein the first contact structure comprises a first end and a second end arranged along the first direction, the first end of the first contact structure is in contact with the conductive structure, and the second end of the first contact structure is between the first end and the first storage structure along the first direction; and
forming a second contact structure that is in contact with the first contact structure and extends along the first direction.

16. The method of claim 15, wherein the forming the first memory cell and the second memory cell comprises:
forming the first semiconductor body surrounded by a first dielectric layer, the second semiconductor body surrounded by a second dielectric layer, and a trench between the first semiconductor body and the second semiconductor body along the second direction, wherein the first semiconductor body comprises a first end and a second end arranged along the first direction, and the second end of the first semiconductor body is connected to a semiconductor layer.

17. The method of claim 16, wherein the forming the conductive structure comprises:
forming a filling structure in the trench, wherein the filling structure comprises a first end and a second end arranged along the first direction, the second end of the filling structure is in contact with a bottom of the trench, and the first end of the filling structure is between the first end of the first semiconductor body and the second end of the first semiconductor body along the first direction;
removing a portion of the first dielectric layer and a portion of the second dielectric layer to form a space adjacent to the first end of the filling structure, wherein the space is between the filling structure and the first end of the first semiconductor body along the first direction, and the space exposes the first semiconductor body and the second semiconductor body in the trench; and
forming the conductive structure in the space, wherein the conductive structure is in contact with the first end of the filling structure.

18. The method of claim 17, wherein the forming the first contact structure comprises:
forming the first contact structure extending into the conductive structure, wherein the first contact structure is between the first end of the filling structure and the first end of the first semiconductor body.

19. The method of claim 18, wherein the forming the second contact structure comprises:
forming a contact hole extending along the first direction, wherein the contact hole extends through the semiconductor layer and the conductive structure and extends into the first contact structure; and
forming the second contact structure by filling a conductive material into the contact hole.

20. The method of claim 15, wherein the forming the first memory cell further comprises:
forming a gate structure adjacent to the first semiconductor body along the second direction, wherein the first transistor further comprises the gate structure;
forming a storage node contact structure in contact with the first semiconductor body along the first direction, wherein the storage node contact structure comprises at least one of a metal layer, a silicide layer, or a doped polysilicon layer; and
forming the first storage structure in contact with the storage node contact structure, wherein the first memory cell further comprises the storage node contact structure between the first semiconductor body and the first storage structure.
